(19) United States
(12) Patent Application Publication
(10) Pub. No.: US 2003/0014707 A1
(43) Pub. Date: Jan. 16, 2003

(54) Code scrambling

(76) Inventors: Brian R. Haug, Chandler, AZ (US); Changguan Fan, Chandler, AZ (US); Meera Desikamani, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/905,269

(22) Filed: Jul. 13, 2001

(51) Int. Cl. H03M 13/00

(52) U.S. Cl. 714/758

(57) ABSTRACT

The present disclosure relates to a method, apparatus and system for scrambling of error and warning codes, or the like. Such method may be used for at least in part deterring fraud or enhancing the security of a system. Such a technique may include detecting an error, scrambling the error code resulting from the error, and making the scrambled error code known.

### BACKGROUND

1. Field

The present disclosure relates to the scrambling of error and warning codes, or the like.

2. Background Information

Presently, error codes are reported in a manner that makes the meaning of the error code known in a repeatable and predictable fashion. In many instances, this allows one, who is attempting to break into or otherwise compromise a device, to do so more easily. For example, many computer systems utilize a username and password scheme to gain access to the computer system's resources. Often those if an invalid username is entered, the computer system will report that the entered username is invalid. This informs an individual who is attempting to compromise the computer system that the entered username is not valid and another username should be attempted. Likewise, if the error code is more obtuse, but repeatable and predictable, the individual may be able to determine, for example, that a certain username generates a particular type of error and that error must, therefore, mean that the username is invalid and a different username should be attempted. Repeatable and predictable error codes, therefore, inadvertently provide information about the system that generates them.

In this context, an error code is any code, message or signal which may represent any discrepancy between, for example, a computed, observed, recorded, or measured quantity and the, for example, true, specified, desired, or theoretically correct value or condition. In this context, the effect an error or the code resulting from that error produces in a device is immaterial.

What is desired is a technique or device that produces a more secure reporting of error codes.

### BRIEF DESCRIPTION OF THE DRAWINGS

The claimed subject matter will be understood more fully from the detailed description given below and from the accompanying drawings of embodiments of the invention which, however, should not be taken to limit the claimed subject matter to the specific embodiments described, but are for explanation and understanding only.

FIG. 1 shows a flow chart diagram illustrating an embodiment of a technique for scrambling an error code in accordance with the claimed subject matter;

FIG. 2 shows a flow chart diagram illustrating an embodiment of a technique for deterring fraud in accordance with the claimed subject matter;

FIG. 3 shows a block diagram illustrating an embodiment of an apparatus for scrambling an error code in accordance with the claimed subject matter.

### DETAILED DESCRIPTION

In the following detailed description, numerous details are set forth in order to provide a thorough understanding of the present claimed subject matter. However, it will be understood by those skilled in the art that the claimed subject matter may be practiced without these specific details. In other instances, well-known methods, procedures, components, and circuits have not been described in detail so as to not obscure the claimed subject matter.

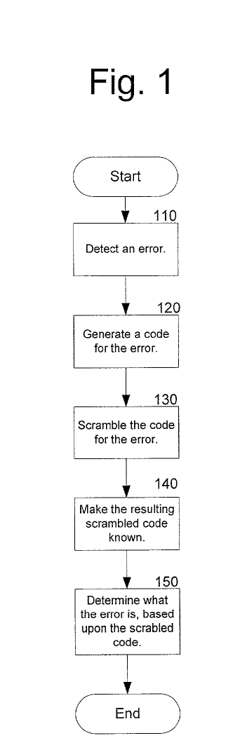

FIG. 1 illustrates an embodiment of a technique to scramble an error code. The technique may include detecting an error, as illustrated by action 110. A code for this error may then be generated, as shown by action 120. As illustrated by action 130, this error code may then be scrambled, through a variety of techniques, such as, for example, obfuscation, encryption or other possible techniques. The error code may be scrambled in such a way as to make it possible to determine the original error code from the scrambled code, as illustrated by action 150. One skilled in the art would realize that a variety of de-scrambling techniques may be utilized, such as, for example, a look-up table, or a de-scrambling calculation. In action 140, the scrambled error code may then be made known, through a variety of possible techniques, such as, for example, displaying the scrambled code on a screen, writing the scrambled code to a file, transmitting the scrambled code to another device or other possible techniques.

In various embodiments, the technique may include generating multiple scrambled codes for a single error code. The creation of the specific scrambled code may depend, such as, for example, at least in part, upon the time at which the scrambled code is generated or, in another example, the way in which the scrambled code may be made known. One skilled in the art will understand that other techniques for generating multiple scrambled codes based, at least in part, upon an error code are possible. In addition, other embodiments, may involve not making the non-scrambled error code known.

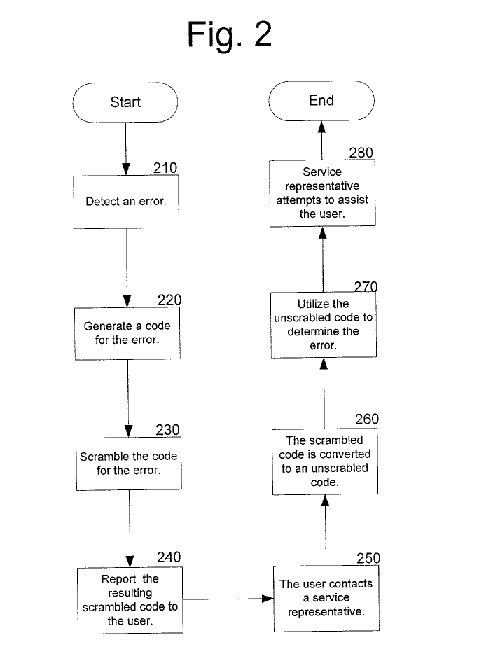

Another embodiment of the claimed subject matter, may involve a technique for at least in part deterring fraud or enhancing the security of a system, as illustrated in FIG. 2. Such a technique may include detecting an error, as illustrated by action 210. In a specific embodiment, to which the claimed subject matter is not limited, a user might attempt to activate a network device; however, one skilled in that art will realize that this technique is not limited to any particular technology. The network device may detect an error during activation or other activity. The network device may scramble the error code resulting from the error, as illustrated by actions 220 and 230. The network device may then report the scrambled error code to the user, as illustrated by action 240. One skilled in the art will realize that there are a variety of ways the scrambled code may be reported to the user, such as, for example, displaying the scrambled code on a screen, via an audio message or response, possibly writing the code to a file; however, these are merely a few examples.

The user, as illustrated by action 250, may then call a service representative for the network device. One skilled in the art will realize that other forms of contacting a service representative may be utilized. One skilled in the art will also realize that, in this context, a service representative is any person or device felt by the user to be responsible for or somewhat capable of assisting the user with the network device, or other appropriate technology. Therefore, many individuals or automated agents may be considered service representatives; however, these are merely examples, which the claimed subject matter is not limited by. The service representative, using the scrambled code, may then unscramble the scrambled code, as illustrated by action 260. There are a number of ways the scrambled code may be converted into an unscrambled code, such as, for example, utilizing a look-up table or possibly performing a decrypting computation. The service representative may then utilize the unscrambled code to determine the original error. One skilled in the art will realize that this may be a trivial matter once the unscrambled code has been generated. As illustrated by action 280, the service representative may attempt to assist the user. They may take a variety of actions to attempt to assist the user. They may, in one example, inform the user what error occurred. Of course, the support staff may not inform the user what error occurred but simply, instead, react in whatever manner is deemed desirable. Also, it is obvious that the attempted assistance may meet with varying levels of success. One skilled in the art will realize that this technique is not limited to network devices or any particular technology. For example, a non-exhaustive list of technologies where this technique may be used includes, but is not limited to: cell phones, credit or phone cards, media centers, subscription services, including subscription entertainment services, or even university course registration.

In various embodiments, the technique may include generating multiple scrambled codes for a single error code. The creation of the specific scrambled code may depend, such as, for example, at least in part, upon the time at which the scrambled code is generated or, in another example, the way in which the scrambled code may be made known. One skilled in the art will understand that other techniques for generating multiple scrambled codes based, at least in part, upon an error code are possible.

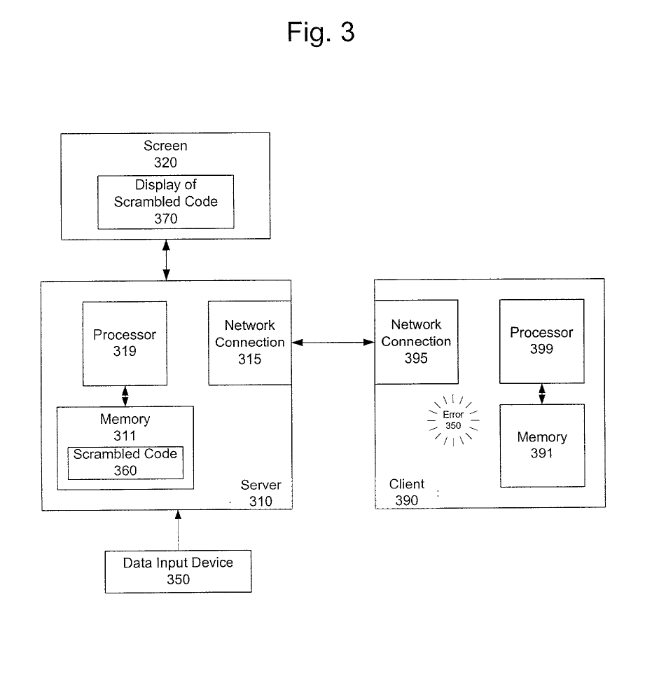

FIG. 3 illustrates an embodiment of an apparatus to scramble an error code. Such an apparatus may include an information handling system, such as, but not limited to a computer, an entertainment system, a cell phone, an Internet appliance, or any other device which includes a processor for processing instructions and a memory for at least temporarily storing the instructions. One skilled in the art will be able to identify a large number of device which may be considered information handling systems.

In the embodiment illustrated by FIG. 3, one such information handling system may be server 310. The server may detect an error. An error may, for example, involve interacting with client 390, as illustrated by error illustrated in FIG. 3, such as, for example, processing a request from the client, receiving an error notification from the client, an internal error on the server not directly related to the client, or, possibly, the server may detect an error on the client. This error may be scrambled, through a variety of techniques, such as, for example, obfuscation, encryption or other possible techniques. This scrambled code may be at least temporarily stored in a section of memory, such as, for example, memory segment 360. The server might then make this scrambled error code known. The server may make the error code known through a variety of techniques, such as, for example, transmitting the scrambled error code to the client for display on the screen, displayed on a screen which is coupled to the server, as shown in element 370, or, possibly, by writing the error code to a file; however, these are merely a few examples, of which the claimed subject matter is not limited to. Of course, one skilled in the art will understand that there are many network configurations that may exist, such as, for example, the server and the client may be the same device, or the server may act as a “client” to the client during other operations. One skilled in the art will understand how to configure the client-server architecture for the particular application at hand.

In another embodiment, the server may generate multiple scrambled codes based upon a single error code. For example, the resulting scrambled code may differ based upon the time the error occurs or is detected. In another example, the resulting scrambled code may differ based upon how, where or to whom the scrambled code is made known. One skilled in the art would understand that other techniques for generating multiple scrambling codes based, at least in part, upon an error code are possible.

In another embodiment, scrambling the error code may be achieved by the following technique. The server may use a substantially predetermined number, M. The server may compute a random or pseudo-random number. This random number may be added to the unscrambled error code. The final scrambled error code may be the subtraction of the result by the random number modulus M. Of course, one skilled in the art will understand that a variety of techniques may be used to generate the scrambled code, such as, for example, a substantially predetermined look up table, or an encryption scheme.

Additional embodiments may include a system illustrated in FIG. 3 where both the server and the client are utilized to scramble an error code. Of course, one skilled in the art will realize that two or more information handling systems, comprising a device for processing instructions, and a memory element to at least temporarily store the instructions, may be used.

In various embodiments, the system may be embodied as a car radio, a radio or television for use in a home entertainment system, a cable/satellite set-top box, a subscription based television receiver, gaming console, cell phone, financial card activation system, Internet appliance or other suitable system or format.

The reader should appreciate that drawings showing methods, and the written descriptions thereof, should also be understood to illustrate machine-accessible media having recorded, encoded, or otherwise embodied therein instructions, functions, routines, control codes, firmware, software, or the like, which, when accessed, read, executed, loaded into, or otherwise utilized by a machine, will cause the machine to perform the illustrated methods. Such media may include, by way of illustration only and not limitation: magnetic, optical, magneto-optical, or other storage mechanisms, fixed or removable discs, drives, tapes, semiconductor memories, organic memories, CD-ROM, CD-R, CD-RW, DVD-ROM, DVD-R, DVD-RW, Zip, floppy, cassette, reel-to-reel, or the like. They may alternatively include down-the-wire, broadcast, or other delivery mechanisms such as Internet, local area network, wide area network, wireless, cellular, cable, laser, satellite, microwave, or other suitable carrier means, over which the instructions etc. may be delivered in the form of packets, serial data, parallel data, or other suitable format. The machine may include, by way of illustration only and not limitation: microprocessor, embedded controller, PLA, PAL, FPGA, ASIC, computer, smart card, networking equipment, or any other machine, apparatus, system, or the like which is adapted to perform functionality defined by such instructions or the like. Such drawings, written descriptions, and corresponding claims may variously be understood as representing the instructions etc. taken alone, the instructions etc. as organized in their particular packet/serial/parallel/etc. form, and/or the instructions etc. together with their storage or carrier media. The reader will further appreciate that such instructions etc. may be recorded or carried in compressed, encrypted, or otherwise encoded format without departing from the scope of this patent, even if the instructions etc. must be decrypted, decompressed, compiled, interpreted, or otherwise manipulated prior to their execution or other utilization by the machine.

Some portions of the detailed description are presented in terms of algorithms and symbolic representations of operations on data bits or binary digital signals within a computer memory. These algorithmic descriptions and representations are the techniques used by those skilled in the data processing arts to convey the substance of their work to others skilled in the art. An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities. Unless specifically stated otherwise, as apparent from the following discussions, it is appreciated that throughout the specification discussions utilizing terms such as “processing” or “computing” or “calculating” or “determining” or the like, refer to the action and processes of a computer or computing system, or similar electronic computing device, that manipulate and transform data represented as physical (electronic) quantities within the computing system's registers and/or memories into other data similarly represented as physical quantities within the computing system's memories, registers or other such information storage, transmission or display devices.

Reference to “subsequent” does not necessarily mean “immediately following”. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the claimed subject matter. The various appearances “an embodiment,” “one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

While certain features of the claimed subject matter have been illustrated and described herein, many modifications, substitutions, changes, and equivalents will now occur to those skilled in the art. It is, therefore, to be understood that the appended claims are intended to cover all such modifications and changes that fall within the true spirit of the claimed subject matter.

What is claimed is:

1: A method comprising:
detecting an error;
scrambling a code for the error; and
making the scrambled code known.

2: The method of claim 1, further comprising determining the error based at least in part upon the scrambled code.

3: The method of claim 2, wherein determining the error based at least in part upon the scrambled code comprises utilizing a look-up table.

4: The method of claim 2, wherein determining the error based at least in part upon the scrambled code comprises a decrypting computation.

5: The method of claim 1, wherein the scrambling comprises generating a first scrambled code upon detecting an error and generating a second scrambled code upon detecting a subsequent occurrence of the error.

6: The method of claim 5, wherein the scrambling comprises determining the scrambled code based, at least in part, upon a substantially random value.

7: The method of claim 6, wherein the scrambling comprises
generating a code for the error;
producing a result by adding a random number to the code for the error; and
subtracting, from the result, the modulus of the random number by a substantially predetermined value.

8: The method of claim 5, wherein the scrambling comprises determining the scrambled code based, at least in part, upon the time at which the error is detected.

9: The method of claim 1, wherein making the scrambled code known comprises making the scrambled code privately available.

10: The method of claim 1, wherein making the scrambled code known comprises making the scrambled code publicly available.

11: The method of claim 10, wherein making the scrambled code publicly available comprises displaying the scrambled code on a screen.

12: The method of claim 10, wherein making the scrambled code publicly available comprises writing the scrambled code to a file.

13: The method of claim 10, wherein making the scrambled code publicly available comprises generating an audio response.

14: A method of deterring fraud comprising:
reporting a scrambled code to a user;
contacting a service representative; and
converting the scrambled code into an unscrambled value.

15: The method of claim 14, wherein reporting a scrambled code comprises detecting an error, scrambling a code for the error and making the scrambled code known.

16: The method of claim 15, wherein scrambling a code for the error comprises generating a first scrambled code upon detecting a first error and generating a second scrambled code upon detecting a second error.

17: The method of claim 15, wherein scrambling a code for the error comprises generating a first scrambled code upon detecting an error and generating a second scrambled code upon detecting a subsequent occurrence of the error, and the second scrambled code is different from the first scrambled code.

18: The method of claim 17, wherein the scrambling comprises determining the scrambled code based, at least in part, upon the time the error is detected.

19: The method of claim 17, wherein scrambling a code for the error comprises generating a first scrambled code upon detecting a first error and again generating the first scrambled code upon detecting a second error.

20: The method of claim 14, wherein contacting a service representative comprises the user using a telephone to call the service representative.

21: The method of claim 20, wherein contacting a service representative comprises selecting a service representative from a group of service representatives.

22: The method of claim 14, wherein converting the scrambled code into an unscrambled value comprises the service representative converting the scrambled code into an unscrambled value.

23: The method of claim 14, wherein converting the scrambled code into an unscrambled value comprises utilizing a look-up table.

24: The method of claim 14, wherein converting the scrambled code into an unscrambled value comprises utilizing a decryption calculation.

25: The method of claim 14, further comprising the service representative, at least attempting, to provide assistance to the user, wherein the type of assistance is determined, at least in part, upon the unscrambled value.

26: The method of claim 25, determining the error based at least in part upon the scrambled code comprises utilizing a look-up table.

27: The method of claim 14, wherein reporting a scrambled code to a user comprises reporting a first scrambled code to a first user and reporting a second scrambled code to a second user, wherein the first and second scrambled codes differ.

28: A method comprising:
detecting a first error;
generating a first scrambled code for the first error;
detecting a subsequent occurrence of the first error; and
generating a second scrambled code for the subsequent occurrence of the first error.

29: The method of claim 28, wherein generating comprises utilizing a substantially random value.

30: The method of claim 29, wherein generating comprises
generating an unscrambled code for the error;
producing a result by adding a random number to the code for the error; and
subtracting, from the result, the modulus of the random number by a substantially predetermined value.

31: The method of claim 28, further comprising making the first and second scrambled codes known.

32: The method of claim 31, further comprising determining the error based at least in part upon the known first and second scrambled codes.

33: The method of claim 32, wherein determining the error based at least in part upon the known first and second scrambled codes comprises utilizing a look-up table.

34: The method of claim 32, wherein determining the error based at least in part upon the known first and second scrambled codes comprises a decrypting computation.

35: The method of claim 31, wherein making the first and second scrambled codes known comprises making at least one of the first and second scrambled codes publicly available.

36: The method of claim 35, wherein making the first and second scrambled codes publicly available comprises displaying the first and second scrambled codes on a screen.

37: The method of claim 35, wherein making the first and second scrambled codes publicly available comprises writing the first and second scrambled codes to a file.

38: The method of claim 35, wherein making the first and second scrambled codes publicly available comprises generating an audio response.

39: The method of claim 28, wherein making the first and second scrambled codes known comprises making at least one of the first and second scrambled codes privately available.

40: A machine accessible medium including thereon instructions which, when executed by a machine, cause the machine to perform a method comprising:
detecting a first error;
generating a first scrambled code for the first error;
detecting a subsequent occurrence of the first error; and
generating a second scrambled code for the subsequent occurrence of the first error.

41: The apparatus of claim 40, wherein generating comprises utilizing a substantially random value.

42: The apparatus of claim 40, further comprising instructions for making the first and second scrambled codes known.

43: The apparatus of claim 42, further comprising instructions for determining the error based at least in part upon the known first and second scrambled codes.

44: The apparatus of claim 43, wherein determining the error based at least in part upon the known first and second scrambled codes comprises utilizing a look-up table.

45: The apparatus of claim 42, wherein making the first and second scrambled codes known comprises making at least one of the first and second scrambled codes publicly available.

46: The apparatus of claim 42, wherein making the first and second scrambled codes publicly available comprises displaying the first and second scrambled codes on a screen.

47: An apparatus comprising:
an information handling system, which further includes a processor for processing instructions and a memory for at least temporarily storing the instructions;
wherein the information handling system is configured to, during operation, detect an error, generate a scrambled code for the error, and make the scrambled code known.

48: The apparatus of claim 47, wherein the apparatus is configured to, during operation, generate the scrambled code in such a way as to allow the error to be derived utilizing the scrambled code.

49: The apparatus of claim 47, wherein the information handling system is configured to, during operation,
generate a first scrambled code upon detection of the error, and
generate a second scrambled code upon detection of a subsequent occurrence of the error;
wherein, the first and second scrambled codes differ.

50: The apparatus of claim 49, wherein the information handling system is configured to, during operation, generate the first and second scrambled codes utilizing a substantially random value.

51: The apparatus of claim 49, wherein the information handling system is configured to, during operation, generate the first and second scrambled codes utilizing a value determined from a second information handling system.

52: The apparatus of claim 47, wherein the information handling system is configured to, during operation, detect an error related to a second information handling system.

53: The apparatus of claim 52, wherein the information handling system is configured to, during operation, detect an error in the settings of the second information handling system.

54: The apparatus of claim 47, wherein the information handling system is configured to, during operation, detect an error in the data input to the information handling system.

55: The apparatus of claim 47, wherein the information handling system is a cell phone.

56: The apparatus of claim 47, wherein the information handling system is a subscription based television receiver.

57: The apparatus of claim 47, wherein the information handling system is a computer.

58: A system comprising:
a first information handling system, which includes a processor for processing instructions and a memory for at least temporarily storing the instructions; and
a second information handling system, which includes a processor for processing instructions and a memory for at least temporarily storing the instructions;
wherein the first and second information handling systems are coupled and
the first information handling system is configured so as to, during operation, detect an error, generate a scrambled code for the error, and make the scrambled code known.

59: The system of claim 58, wherein the second information handling system has a configuration so as to, during operation, derive the error utilizing the scrambled code.

60: The system of claim 58, wherein the first information handling system has a configuration so as to, during operation,
generate a first scrambled code upon detection of the error, and
generate a second scrambled code upon detection of a subsequent occurrence of the error;
wherein, the first and second scrambled codes differ.
